(19) United States
(12) Patent Application Publication
(10) Pub. No.: US 2007/0249149 A1
(43) Pub. Date: Oct. 25, 2007

(54) IMPROVED THERMAL BUDGET USING NICKEL BASED SILICIDES FOR ENHANCED SEMICONDUCTOR DEVICE PERFORMANCE

(75) Inventors: Sadanand V. Deshpande, Lagrangeville, NY (US); Jay W. Strane, Warwick, NY (US); Michael P. Belyansky, Bethel, CT (US); Christian Lavoie, Ossining, NY (US)

Correspondence Address: SCULLY SCOTT MURPHY & PRESSER, PC, 400 GARDEN CITY PLAZA, SUITE 300, GARDEN CITY, NY, 11530, US

(73) Assignee: International Business Machines Corporation, Armonk, NY (US)

(21) Appl. No.: 11/379,651

(22) Filed: Apr. 21, 2006

(51) Int. Cl. H01L 21/4763; H01L 21/44

(52) U.S. Cl. 438/592; 438/682

(57) ABSTRACT

The use of nickel, Ni, based alloys that enables higher contact module which, in turn, provides the device designers additional gains in transistor speeds is provided. Specifically, the use of Ni based alloys for silicide formation in 90 nm technologies and beyond enables higher temperature (greater than 450° C.) processing in the contact module for advanced devices. This capability of higher thermal budget in processing stress inducing films in the contact module helps enhance device performance beyond what is possible with conventional pure Ni based silicides. Another benefit of this application is the deposition temperature of the contact dielectric (e.g., pre-metal dielectric) can be increased to enable moisture free, denser, higher quality films.

### FIELD OF THE INVENTION

The present invention relates to a semiconductor structure and a method of fabricating the same. More particularly, the present invention relates to a semiconductor structure including nickel based silicide contacts that enable higher temperature processing in the contact module which, in turn, permit the fabrication of semiconductor devices having enhanced performance.

### BACKGROUND OF THE INVENTION

In order to be able to fabricate integrated circuits (ICs) of increased performance than is currently feasible, device contacts must be developed which reduce the electrical contact resistance to the ICs' Si body or integrated electronic device formed therein. A contact is the electrical connection, at the semiconductor surface, between the devices in the semiconductor wafer and the metal layers, which serve as interconnects. Interconnects serve as the metal wiring that carry electrical signals throughout the chip.

Silicide contacts are of specific importance to IC's, including complementary metal oxide semiconductor (CMOS) devices because of the need to reduce the electrical resistance of the many Si contacts, at the source/drain and gate regions, in order to increase chip performance. Silicides are metal compounds that are thermally stable and provide for low electrical resistivity at the Si/metal interface. Silicides generally have lower barrier heights thereby improving the contact resistance. Reducing contact resistance improves device speed therefore increasing device performance.

Silicide formation typically requires depositing a refractory metal such as Ni, Co or Ti onto the surface of a Si-containing material or wafer. Conventional processing of Ni silicide films begins with depositing a Ni layer with a thickness of about 8 to 12 nm.

The thickness of the resulting silicide is twice the thickness of the deposited Ni layer, i.e., Ni layers with a thickness of about 8 to 12 nm form silicides with a thickness of about 16 to 24 nm, respectively. Following deposition, the structure is then subjected to an annealing step using conventional processes such as, but not limited to: rapid thermal annealing. During thermal annealing, the deposited metal reacts with Si forming a metal silicide. Following the anneal, a 10 nm Ni metal layer forms a Ni silicide that has a thickness of approximately 20 nm.

Ni may serve as a metal for silicide formation. One advantage of Ni silicides is that Ni monosilicide contacts consume less Si than conventional Ti or Co silicide contacts. A disadvantage of Ni silicide contacts is that the higher resistivity Ni disilicide phase is produced during high temperature processing steps, rather than the preferred lower resistivity Ni monosilicide phase. The formation of the Ni disilicide phase is nucleation controlled and disadvantageously consumes more Si than the preferred Ni monosilicide phase. Ni disilicides produce a rougher silicide/Si wafer interface and also have a higher sheet resistivity than the preferred Ni mono-silicide phase. A second disadvantage is that thin Ni monosilicide films tend to become discontinuous before Ni disilicide formation leading to high resistivity.

U.S. Pat. No. 6,905,560 to Cabral, Jr. et al. provides a method for forming low resistance, non-agglomerated Ni monosilicide contact. In accordance with the '560 patent, the low resistance, non-agglomerated Ni monosilicide contacts are formed by utilizing a metal alloy layer which includes Ni and at least one alloying additive, in place of pure Ni in a salicidation process. In addition to being non-agglomerated and having a low resistance, the Ni monosilicide contacts provided in the '560 patent are able to withstand high processing temperatures associated with conventional semiconductor production, without negatively impacting the performance of the contact.

Although the '560 patent describes a method of fabricating non-agglomerated Ni monosilicide contacts, there is no teaching therein that the same can be used to enable a higher thermal budget in processing stress-inducing films for enhanced stress engineering and/or more robust (i.e., moisture free) dielectrics for interconnect use.

### SUMMARY Of THE INVENTION

The present invention relates to the use of nickel, Ni, based alloys to enable higher contact module which, in turn, provides the device designers additional gains in transistor speeds. In one embodiment, up to 10% nFET enhancement can be achieved by the present invention. In the past, it has been difficult to improve nFET performance and this invention enables a better device design point.

The use of Ni based alloys for silicide formation in 90 nm technologies and beyond enables higher temperature (greater than 450° C.) processing in the contact module for advanced devices. This capability of higher thermal budget in processing stress inducing films in the contact module enhances device performance beyond what is possible with conventional pure Ni based silicides. Current device structures cannot use higher temperatures (greater than 400° C.) due to the instability of the pure Ni based silicides.

Another benefit of this application is the deposition temperature of the contact dielectric (e.g., pre-metal dielectric) can be increased to enable moisture free films. By “moisture free” it is meant that the pre-metal dielectric has a moisture content of less than 1%. An increase in deposition temperature also allows one to obtain higher quality, denser dielectric films. For pure Ni based silicides, the deposition temperature is limited to 400° C. due to the instability of the pure Ni based silicides.

In one aspect of the present invention, a method of forming a semiconductor structure is provided that includes:
forming at least one field effect transistor on a surface of a semiconductor substrate, said semiconductor substrate having a device channel in a region of said substrate beneath a gate electrode of said at least one field effect transistor, said device channel is confined by adjoining source/drain regions;
forming a Ni alloy monosilicide contact on at least one of said source/drain regions or said gate electrode; and
forming at least one of a stress inducing layer or a pre-metal dielectric on said semiconductor substrate and said at least one field effect transistor at a temperature of greater than 450° C.

Another aspect of the present invention relates to a semiconductor structure that is fabricated utilizing the method of the present application. The inventive semiconductor structure includes:
at least one field effect transistor on a surface of a semiconductor substrate, said semiconductor substrate having a device channel in a region of said substrate beneath a gate electrode of said at least one field effect transistor, said device channel is confined by adjoining source/drain regions;
a Ni alloy monosilicide contact on at least one of said source/drain regions or said gate electrode; and
at least one of a stress inducing layer or a pre-metal dielectric on said semiconductor substrate and said at least one field effect transistor.

### BRIEF DESCRIPTION OF THE DRAWINGS

FIGS. 1A-1C are pictorial representations (through cross sectional views) illustrating the basic processing steps of the present invention in fabricating a semiconductor structure including Ni alloy silicide contacts and a stress inducing layer.

FIG. 2 is a pictorial representation (through a cross sectional view) illustrating a semiconductor structure in accordance with the present invention including a Ni alloy silicide contact and a pre-metal dielectric.

FIG. 3 is a pictorial representation (through a cross sectional view) illustrating a semiconductor structure in accordance with the present invention including Ni alloy monosilicide contacts, a stress inducing layer and a pre-metal dielectric.

### DETAILED DESCRIPTION OF THE INVENTION

The present invention, which provides an improved thermal budget using Ni alloy monosilicides for enhanced semiconductor device manufacturing, will now be described in greater detail by referring to the following discussion and drawings that accompany the present application. It is noted that the drawings of the present application are provided for illustrative purposes and, as such, the drawings are not drawn to scale.

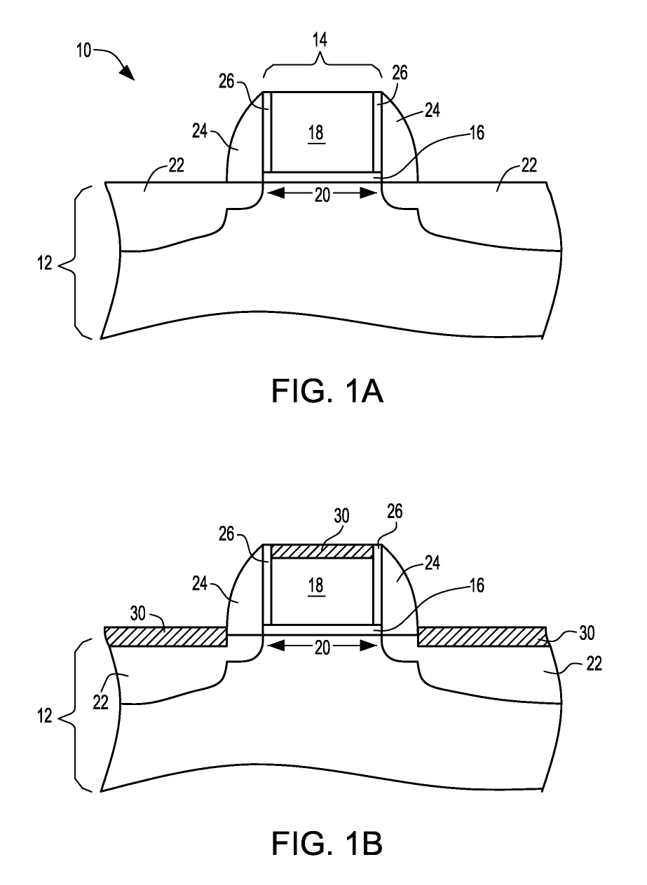

The present invention begins by first providing the initial structure 10 shown in FIG. 1. The initial structure 10 includes a semiconductor substrate 12 having at least one field effect transistor (FET) 14 located thereon. The at least one FET 14 may be an nFET or a pFET, with nFETs being highly preferred in the present invention. Combinations of pFETs and nFETs are also contemplated in the present invention.

The at least one FET 14 includes a gate dielectric 16 located on a surface of the substrate and a gate electrode 18 located on the gate dielectric 16. Each FET includes a channel region 20 located within the substrate 12 and beneath the gate dielectric/gate electrode stack. Source/drain regions 22 are located adjacent to said channel region 20. Each FET may also include at least one sidewall spacer 24 and a passivation layer 26 present on the sidewalls of at least the gate conductor, as shown in FIG. 1A. The at least one sidewall spacer 24 and the passivation layer 26 are optional, and need not be used in all instances.

The at least one FET 14 is fabricated using conventional complementary metal oxide semiconductor processing techniques well known to those skilled in the art. For example, deposition of various material layers, lithography, etching, ion implantation and annealing can be used in forming the FETs. The at least one FET 14 can also be formed utilizing a replacement gate process.

The semiconductor substrate 12 includes any semiconductor material including, for example, Si, SiC, SiGeC, Ge, SiGe, Ga, GaAs, InAs, InP as well as other III/V or II/VI compound semiconductors. Layered semiconductors such as, for example, Si/SiGe and semiconductor-on-insulators (SOIs) are also contemplated herein. Typically, the semiconductor substrate 12 is a Si-containing semiconductor such as, for example, Si, SiC, SiGe, SiGeC, or a silicon-on-insulator. The substrate 12 may be unstrained, strained or include regions of strain and unstrain therein. The substrate 12 may be intrinsic or it may be doped with, for example, but not limited to: B, As or P.

When SOI substrates are employed, those substrates include top and bottom semiconductor, e.g., Si, layers that are separated at least in part by a buried insulating layer. The buried insulating layer includes, for example, a crystalline or non-crystalline oxide, nitride or any combination thereof. Preferably, the buried insulating layer is an oxide. Typically, the buried insulating layer is formed during initial stages of a layer transfer process or during an ion implantation and annealing process, such as, for example, SIMOX (separation by ion implantation of oxygen).

The substrate 12 may have a single crystal orientation or alternatively hybrid semiconductor substrates having surface regions of different crystal orientations can also be employed. The hybrid substrate allows for fabricating a FET upon a specific crystal orientation that enhances the performance of each FET formed. For example, the hybrid substrate allows for providing a structure in which a pFET can be formed on a (110) crystal orientation, while the nFET can be formed on a (100) crystal orientation. When a hybrid substrate is used, it may have SOI-like properties, bulk-like properties or a combination of SOI- and bulk-like properties.

In some embodiments of the present invention, at least one isolation region (not shown) is formed into the substrate 12. The at least one isolation region may include a trench isolation region, a field oxide isolation region or combinations thereof. The isolation regions are formed utilizing processing techniques well known to those skilled in the art.

The gate dielectric 16 present in each of the FETs can comprise the same or different insulating material. For example, the gate dielectric 16 can be comprised of an oxide, nitride, oxynitride, high k material (i.e., a dielectric material having a dielectric constant that is greater than silicon dioxide) or any combination thereof including multilayers. Preferably, the gate dielectric 16 is comprised of an oxide such as, for example, SiO₂. The gate electrode 18 of each FET can be comprised of the same or different conductive material, including, for example, polySi, SiGe, a metal, a metal alloy, a metal silicide, a metal nitride or combinations including multilayers thereof. When multilayers are present, a diffusion barrier (not shown), such as TiN or TaN, can be positioned between each of the conductive layers. A capping layer (also not shown), such as an oxide, or nitride, can be located atop the gate electrode of each of the FETs; the presence of the capping layer can be used to prevent subsequent formation of a silicide contact on said gate electrode. The silicide contact on said gate electrode is typically formed when the gate electrode includes a Si-containing material and no capping layer is present.

The at least one spacer 24 that is optionally present is typically comprised of an oxide, nitride or oxynitride including combinations and multilayers thereof. Although optional, typically one spacer 24 is present in the inventive structure. In embodiments in which passivation layer 26 is present, that layer is typically comprised of an oxide, nitride or oxynitride.

As indicated above, each FET 14 also includes S/D regions 22 which typically include extension regions and deep S/D diffusion regions. The source/drain regions 22 together with the gate electrode 18 define the length of the channel 20. It is noted that S/D extensions and S/D diffusion regions are comprised of an upper portion of the semiconductor substrate 12 that has been doped with either n- or p-type dopants by ion implantation. The S/D extensions are typically shallower in depth than the S/D diffusion regions.

After processing the initial structure 10 shown in FIG. 1A, Ni alloy monosilicide contacts 30 are formed above the source/drain regions 22, the gate electrode 18 or both. FIG. 1B shows a structure including Ni alloy monosilicide contacts 30 located above both the source/drain regions 22 and the gate electrode 18. In some embodiments not shown, a fully silicided gate electrode (FUSE) can be formed during this stage of the present invention. When a FUSE is formed, the FUSE takes the place of the gate electrode 18 and the Ni alloy silicide contact 30 that is located thereabove.

The term “Ni alloy monosilicide contact” is used throughout the present application to denote a Ni monosilicide phase which includes at least one alloying additive therein. The alloying additive may comprise at least one of C, Al, Si, Sc, Ti, V, Co, Cr, Mn, Fe, Cu, Y, Zr, Nb, Rh, In, Sn, La, Mo, Hf, Ta, W, Re, Pt, Ce, Pr, Nd, Sm, Eu, Gd, Tb, Dy, So, Er, Tm, Yb, Lu and mixtures thereof. Of the above mentioned additives, Ti, V, Cr, Zr, Nb, Mo, Hf, Ta, W and Re are particularly preferred. The alloying additive is present in the final Ni alloy monosilicide contact in an amount from about 0.01 atomic % to about 50 atomic percent, with an amount from about 0.01 to about 20 atomic percent being more preferred.

The structure formed in FIG. 1B is formed by first providing a Ni alloy layer or a stack including Ni and another layer including the alloying additive (herein after Ni, alloying additive-containing stack) over the structure shown in FIG. 1A. In some embodiments, a Si-containing material including, but are not limited to: Si, single crystal Si, polycrystalline Si, SiGe, amorphous Si, and annealed poly Si, can be formed prior to the formation of the Ni alloy layer or Ni, alloying additive-containing stack.

When a Ni alloy layer is employed, the Ni alloy may be formed using conventional deposition techniques including, but not limited to: chemical vapor deposition (CVD), plasma-assisted CVD, high-density chemical vapor deposition (HDCVD), plating, sputtering, evaporation and chemical solution deposition. The deposition of the Ni alloy layer is continued until an initial thickness of about 30 nm or less, preferably about 15 nm or less, even more preferably about 10 nm or less, is produced.

The at least one alloying additive mentioned may be formed initially within a Ni alloy layer during metal alloy deposition, by co-deposition or deposition from an alloy target. Alternatively, the alloying additive may be introduced to the Ni metal layer via ion implantation. Ion implantation techniques use either ion beam mixing of different ion types to produce a desired composition, or implantation of a desired species of alloying additives in a proportion needed to achieve proper stoichiometry.

When a Ni, alloying additive-containing stack is employed, the alloying additive is introduced as a discrete layer on top of a Ni film through bilayer or multiplayer deposition.

A barrier layer may be optionally formed over the metal alloy layer or Ni, alloying additive-containing stack at this point of the invention. The optional barrier layer may comprise any material that protects the Ni metal alloy layer from oxidation. Examples of materials suitable for barrier layers include, but are not limited to: SiN, TaN, TiON, TiN and mixtures thereof. The optional barrier layer is removed during annealing of the metal alloy layer or the Ni, alloying additive-containing stack.

Annealing is then performed at a temperature that is effective in converting a portion (or all) of the metal alloy layer or the Ni, alloying additive-containing stack into a Ni alloy monosilicide; the converting takes place in areas in which the Ni alloy layer or the Ni, alloying additive-containing stack are in contact with a Si-containing material. This thermal anneal is typically conducted using Rapid Thermal Anneal (RTA), yet other conventional annealing processes are also contemplated such as furnace annealing, spike annealing, laser annealing or microwave annealing. Consistent with conventional semiconductor device production a thermal dose of about 650° C. for approximately 30 minutes is appropriate. Other temperatures, which are appropriate for annealing, include from about 250° to 600° C., most preferably from about 400° C. to 550° C.

In some embodiments, an optional second anneal is performed at a temperature that is effective to further reduce the resistance of the silicide contact. When preformed, the second anneal is typically carried out at a temperature of about 500° to 700° C., most preferably from 500° to 600° C.

Low temperature anneals generally form metal rich silicide phases, which resist selective etch process steps. Low temperature anneals are conducted at less than about 500° C., preferably lower than about 350° C. The metal rich phases could be: Ni₃Si₂, Ni₂Si, and possibly even Ni₃₁Si₁₂ and Nᵢ₃Si, where the Ni content is higher than the Si content. When a metal rich phase is produced a second higher temperature anneal is required to form the low resistivity Ni monosilicide.

Following the formation of the Ni alloy monosilicide contact 30, the unreacted remaining portions of the Ni metal alloy layer (or the Ni, alloying additive-containing stack) are removed using a conventional etch process, such as wet etching, reactive-ion etching (RIE), ion beam etching, or plasma etching. The resultant non-agglomerated Ni monosilicide layer that remains is more resistive to etch processing steps when compared to the non-reacted metal layer that is removed during the etching step. The final thickness of the Ni alloy monosilicide contact 30 ranges from about 15 nm to about 35 nm.

Next, a stress inducing liner 32 can be formed on top of portions of the substrate 12 as well the FETs. The resultant structure including the stress inducing liner 32 is shown, for example, in FIG. 1C. The stress inducing liner 32, which may be under compressive or tensile stress; a tensile stress inducing liner is typically used for nFETs, while a compressively stress inducing liner is typically for pFETs. When both nFETs and pFETs are present, a dual stress inducing liner is used. The stress inducing line may comprise a single layer or multiple layers.

The liner 32 is comprised of any stress inducing material such as, for example, a nitride. The stress inducing liner 32 can formed by various deposition processes including for example, chemical vapor deposition (CVD), plasma enhanced chemical vapor deposition (PECVD), rapid thermal chemical vapor deposition (RTCVD) or atomic layer deposition (ALD). The deposition of the stress inducing liner 32 can be preformed at high processing temperatures because of the presence of the Ni alloy monosilicide contacts 30. By “high processing temperatures” it is meant that the deposition can be carried out at a temperature of greater than 450° C., preferably from about 500° to about 600° C. The higher deposition temperature of the stress inducing liner 32 results in a higher stressed liner material being formed which, in turn, produces a higher strained channel. Typically, the stress inducing layer has a tensile strength of greater than about 1400 MPa. In some embodiments, a stressed liner having a tensile strength of 1590 MPa can be achieved when a deposition temperature of 550° C. is used, as compared to a stress value of less than 1430 MPa, when a deposition temperature of less than 450° C. is employed. The same is true for a compressive liner process, which shows higher stress at elevated deposition temperature. For example, the same compressive stressed liner process shows a compressive stress of −2300 MPa and of −2550 MPa being deposited at 400° C. and 480° C. respectively. Therefore, higher temperature budget is beneficial for both nFET and pFET performance.

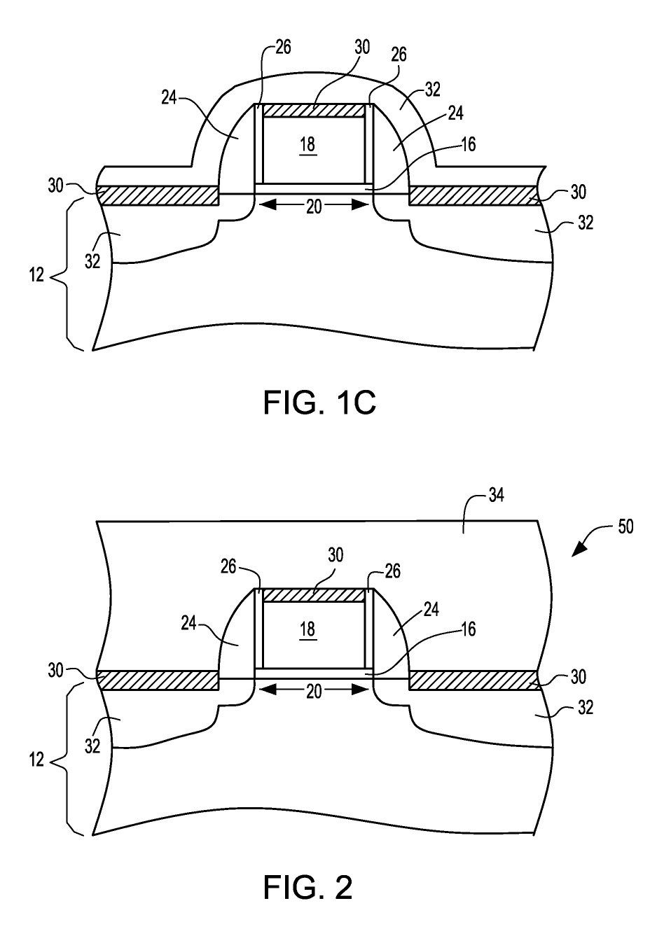

FIG. 2 is a pictorial representation (through a cross sectional view) illustrating a semiconductor structure 50 in accordance with the present invention including a Ni alloy silicide contact 30 and a pre-metal dielectric 34. The structure 50 shown in FIG. 2 is formed by first providing the structure shown in FIG. 1B of the present invention. Next, a pre-metal dielectric 34 is deposited atop the structure shown in FIG. 1B. The pre-metal dielectric layer 34 comprises at least one dielectric material that is deposited at the high processing temperatures mentioned above (i.e., at a temperature of greater than 450° C.). CVD, PECVD, RTCVD, ALD are examples of various deposition techniques that can be used in forming the pre-metal dielectric 34. Such pre-metal dielectrics include, for example, oxide layers based on ozone-TEOS or silane chemistries which are commonly called by a generic term of undoped silica glass (USG). Also, higher temperature budget allows one to use doped oxides (usually doped by phosphorus or boron). Doping allows one to achieve either better reliability (phosphorus is known to getter impurities like sodium or potassium) or better gap fill properties (boron is known to flow at elevated temperature and close any voids in dielectric). Doped oxides typically require higher temperatures (550-600° C.) in order to anneal a dopant and prevent it from being oxidized in air. Therefore, these dielectrics, which are deposited at temperatures greater than 450° C., are more robust than conventional dielectrics that are deposited at lower deposition temperatures.

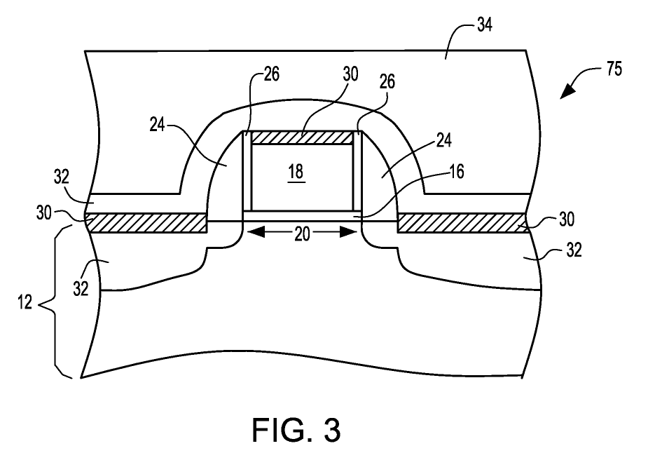

FIG. 3 is a pictorial representation (through a cross sectional view) illustrating a semiconductor structure 75 in accordance with the present invention including Ni alloy monosilicide contacts 30, a stress inducing layer 32 and a pre-metal dielectric 34. This structure 75 is first formed by providing the structure shown in FIG. 1C. Next, the pre-metal dielectric 334 is deposited as described above.

While the present invention has been particularly shown and described with respect to preferred embodiments thereof, it will be understood by those skilled in the art that the foregoing and other changes in forms and details may be made without departing from the spirit and scope of the present invention. It is therefore intended that the present invention not be limited to the exact forms and details described and illustrated, but fall within the scope of the appended claims.

What is claimed is:

1. A method of fabricating a semiconductor structure comprising:
forming at least one field effect transistor on a surface of a semiconductor substrate, said semiconductor substrate having a device channel in a region of said substrate beneath a gate electrode of said at least one field effect transistor, said device channel is confined by adjoining source/drain regions;
forming a Ni alloy monosilicide contact on at least one of said source/drain regions or said gate electrode; and
forming at least one of a stress inducing layer or a pre-metal dielectric on said semiconductor substrate and said at least one field effect transistor at a temperature of greater than 45° C.

2. The method of claim 1 wherein said forming said Ni alloy monosilicide contact comprises forming a Ni alloy layer or a Ni, alloying additive-containing stack atop said semiconductor substrate and said at least one field effect transistor and annealing to convert said Ni alloy layer or said Ni, alloying additive-containing stack, in contact with a Si-containing material, into said Ni alloy monosilicide contact.

3. The method of claim 2 wherein said Ni alloy layer and said Ni, alloying additive-containing stack comprise Ni and at least one alloying additive selected from the group consisting of C, Al, Si, Sc, Ti, V, Co, Cr, Mn, Fe, Cu, Y, Zr, Nb, Rh, In, Sn, La, Mo, Hf, Ta, W, Re, Pt, Ce, Pr, Nd, Sm, Eu, Gd, Tb, Dy, So, Er, Tm, Yb, Lu and mixtures thereof.

4. The method of claim 3 wherein said alloying additive is one of Ti, V, Cr, Zr, Nb, Mo, Hf, Ta, W or Re.

5. The method of claim 1 wherein said Ni alloy monosilicide contact includes from about 0.01 atomic % to about 50 atomic % of at least one alloying additive, said at least one alloying additive comprising C, Al, Si, Sc, Ti, V, Co, Cr, Mn, Fe, Cu, Y, Zr, Nb, Rh, In, Sn, La, Mo, Hf, Ta, W, Re, Pt, Ce, Pr, Nd, Sm, Eu, Gd, Tb, Dy, So, Er, Tm, Yb or Lu.

6. The method of claim 1 wherein said stress inducing layer is formed and said stress inducing layer comprises a nitride.

7. The method of claim 6 wherein said stress inducing layer comprises a tensile stressed liner and said at least one field effect transistor is an nFET.

8. The method of claim 7 wherein said stress inducing layer has a tensile strength of greater than about 1400 MPa.

9. The method of claim 1 wherein said pre-metal dielectric is formed and said pre-metal dielectric comprises of an oxide based undoped silica glass layer or a doped oxide layer.

10. The method of claim 2 wherein said annealing is a first anneal step which is followed by a second annealing step.

11. The method of claim 10 wherein said first annealing step is carried out a first temperature from about 250° to 600° C., and said second annealing step is carried out at a second temperature from about 500° to about 700° C.

12. A semiconductor structure comprising:
at least one field effect transistor on a surface of a semiconductor substrate, said semiconductor substrate having a device channel in a region of said substrate beneath a gate electrode of said at least one field effect transistor, said device channel is confined by adjoining source/drain regions;
a Ni alloy monosilicide contact on at least one of said source/drain regions or said gate electrode; and
at least one of a stress inducing layer or a pre-metal dielectric on said semiconductor substrate and said at least one field effect transistor.

13. The semiconductor structure of claim 12 wherein said stress inducing layer is present and comprises a nitride layer.

14. The semiconductor structure of claim 13 wherein said stress inducing layer comprises a tensile stressed liner and said at least one field effect transistor is an nFET.

15. The semiconductor structure of claim 14 wherein said stress inducing layer has a tensile strength of greater than about 1400 MPa.

16. The semiconductor structure of claim 14 wherein said semiconductor substrate is a hybrid substrate in which the nFET is located on a (100) crystal orientation.

17. The semiconductor structure of claim 12 wherein said pre-metal dielectric comprises one of oxide-based undoped silica glass or a doped oxide layer.

18. The semiconductor structure of claim 12 wherein said Ni alloy monosilicide contact includes Ni and from about 0.01 atomic % to about 50 atomic % of at least one alloying additive.

19. The semiconductor structure of claim 18 wherein said at least alloying additive comprises C, Al, Si, Sc, Ti, V, Co, Cr, Mn, Fe, Cu, Y, Zr, Nb, Rh, In, Sn, La, Mo, Hf, Ta, W, Re, Pt, Ce, Pr, Nd, Sm, Eu, Gd, Tb, Dy, So, Er, Tm, Yb or Lu.

20. The semiconductor structure of claim 19 said alloying additive is one of Ti, V, Cr, Zr, Nb, Mo, Hf, Ta, W or Re.
